(19) United States
(12) Patent Application Publication
(10) Pub. No.: US 2026/0075734 A1
(43) Pub. Date: Mar. 12, 2026

(54) ELECTRONIC DEVICE AND DISPLAY DEVICE

(71) Applicant: SAMSUNG ELECTRONICS CO., LTD., Suwon-si (KR)

(72) Inventors: Jungwoo Yang, Suwon-si (KR); Junyoung Ko, Suwon-si (KR); Kangmoon Seo, Suwon-si (KR)

(73) Assignee: SAMSUNG ELECTRONICS CO., LTD., Suwon-si (KR)

(21) Appl. No.: 19/262,980

(22) Filed: Jul. 8, 2025

Related U.S. Application Data
(63) Continuation of application No. PCT/KR2025/008790, filed on Jun. 24, 2025.

(30) Foreign Application Priority Data
Sep. 10, 2024 (KR) 10-2024-0123567

(51) Int. Cl. H05K 5/02

(52) U.S. Cl. CPC H05K 5/0247

(57) ABSTRACT

An electronic device including a printed circuit board and a power inlet provided on the printed circuit board. The power inlet includes a first terminals a second terminal at a first side of the first terminal, and a third terminal at a second side of the first terminal. The second side is opposite to the first side. A first fixing portion is fixed on the printed circuit board by a fastening member. A first fastening support is soldered on the printed circuit board and fixes the first fixing portion on the printed circuit board.

### CROSS-REFERENCE TO RELATED APPLICATIONS

This application is a bypass continuation of International Application No. PCT/KR2025/008790, filed on Jun. 24, 2025, which is based on and claims priority to Korean Patent Application No. 10-2024-0123567, filed on Sep. 10, 2024, in the Korean Intellectual Property Office, the disclosures of which are incorporated by reference herein in their entireties.

### BACKGROUND

### 1. Field

The disclosure relates to an electronic device and display device including a power supply board.

### 2. Description of Related Art

An electronic device, such as a display device, may include a power supply board that supplies power to drive the electronic device. For example, the power supply board may be a Switched Mode Power Supply (SMPS) board.

The power supply board includes a power inlet to connect to a power cord. For example, the power inlet may be provided on a substrate of the power supply board. The power inlet is detachably connected to the power cord. For example, the power supply board may convert alternating current (AC) power received through the power inlet into a preset level of DC power.

The power inlet may include a plurality of terminals. For example, the power inlet may include a ground terminal, a live terminal, and a neutral terminal. The power supply board may be applied AC power through the live terminal and the neutral terminal.

The power inlet may include a lead for mounting the power inlet on the substrate, and in the case in which the lead penetrates the substrate and protrudes from the substrate, the thickness of the power supply board increases. Also, in the case of separating the power cord connected to the power inlet from the power inlet with a force that is greater than a preset magnitude, the power inlet may be damaged or depart from the substrate, which may threaten the safety of the electronic device.

### SUMMARY

Provided are an electronic device and display device with a reduced thickness.

Further, provided are an electronic device and display device which may have improved safety.

The technical object intended to be achieved by the present document is not limited to the above-mentioned technical objects, and other technical objects not mentioned will be clearly understood by one of ordinary skill in the technical art to which the disclosure belongs from the following description.

According to an aspect of the disclosure, there is provided an electronic device including: a printed circuit board; and a power inlet provided on the printed circuit board, wherein the power inlet includes: a first terminal; a second terminal at a first side of the first terminal; a third terminal at a second side of the first terminal, the second side being opposite to the first side; a first fixing portion fixed on the printed circuit board by a fastening member; and a first fastening support soldered on the printed circuit board and configured to fix the first fixing portion on the printed circuit board.

The power inlet may include: a first cord coupling portion accommodating the first terminal; a second cord coupling portion accommodating the second terminal and partitioned from the first cord coupling portion; and a third cord coupling portion accommodating the third terminal and partitioned from the first cord coupling portion.

The power inlet may include: a first partition wall partitioning the first cord coupling portion from the second cord coupling portion; and a second partition wall partitioning the first cord coupling portion from the third cord coupling portion.

A power cord may be configured to be detachably coupled to the power inlet, wherein a cross section of the first cord coupling portion, which is perpendicular to a direction in which the power cord is coupled, has a shape that is different from a cross section of the second cord coupling portion, which is perpendicular to the direction in which the power cord is coupled, or a cross section of the third cord coupling portion, which is perpendicular to the direction in which the power cord is coupled.

The power cord may include: a first connector portion configured to be inserted into the first cord coupling portion; a second connector portion configured to be inserted into the second cord coupling portion, and spaced from a first side of the first connector portion; and a third connector portion configured to be inserted into the third cord coupling portion, and spaced from a second side of the first connector portion, the second side being opposite to the first side of the first connector portion.

The electronic apparatus may include a fastening member configured to be coupled to the first fastening support.

The first fastening support may include a first lead portion of which a part is soldered on the printed circuit board, wherein the printed circuit board may include a first fixing hole accommodating the first lead portion, and wherein the first lead portion is accommodated in the first fixing hole through a first surface of the printed circuit board without protruding from a second surface of the printed circuit board, the second surface being opposite to the first surface.

The first fixing portion may include a first supply hole formed to allow heat to be supplied to the part of the first lead portion soldered on the printed circuit board.

The first fastening support may include a washer portion between the fastening member and the first fixing portion, and wherein the washer portion may include a washer protrusion protruding toward the fastening member.

The first terminal may include a ground terminal, and wherein the fastening member is grounded with the ground terminal according to the first fastening support being connected to a ground pattern provided on the printed circuit board by soldering.

The power inlet may include: a second fixing portion at a second end of the power inlet, the second end being opposite to a first end of the power inlet at which the first fixing portion is positioned; and a second fastening support configured to fix the second fixing portion on the printed circuit board by being soldered on the printed circuit board.

The second fastening support may include a second lead portion of which a part is soldered on the printed circuit board, wherein the printed circuit board may include a second fixing hole accommodating the second lead portion, and wherein the second lead portion is accommodated in the second fixing hole through a first surface of the printed circuit board without protruding from a second surface of the printed circuit board, the second surface being opposite to the first surface.

The second fixing portion may include a second supply hole formed to allow heat to be supplied to the part of the second lead portion soldered on the printed circuit board.

The electronic apparatus may include a display panel; and a bottom chassis covering the display panel, wherein the fastening member is fastened to the bottom chassis.

According to an aspect of the disclosure there is provided a display device including: a display panel; and a power supply board configured to receive power to be supplied to the display panel, the power supply board including a printed circuit board and a power inlet mounted on the printed circuit board, wherein the power inlet includes: a first cord coupling portion; a second cord coupling portion at a first side of the first cord coupling portion and partitioned from the first cord coupling portion; a third cord coupling portion at a second side of the first cord coupling portion, the second side being opposite to the first side, the third cord coupling portion partitioned from the first cord coupling portion; a first fixing portion fixed on the printed circuit board according to a first fastening support being soldered on the printed circuit board, the first fixing portion including a first supply hole formed to allow heat to be supplied to a part of the first fastening support being soldered; and a fastening member fastened to the first fixing portion and the first fastening support and configured to fix the power inlet on the printed circuit board.

### BRIEF DESCRIPTION OF THE DRAWINGS

The above and other aspects and features of embodiments of the disclosure will become more apparent from the following detailed description taken in conjunction with the accompanying drawings, in which:

FIG. 1 shows an electronic device according to an embodiment of the disclosure;

FIG. 2 shows a state in which a rear cover has been detached from an electronic device according to an embodiment of the disclosure;

FIG. 3 shows a portion of a power supply board according to an embodiment of the disclosure;

FIG. 4 is an exploded view of a power cord and some components of a power supply board according to an embodiment of the disclosure;

FIG. 5 shows a cross section taken along line A-A′ denoted in FIG. 3;

FIG. 6 shows a cross section taken along line B-B′ denoted in FIG. 3;

FIG. 7 shows a portion of a power supply board according to an embodiment of the disclosure; and

FIG. 8 is an exploded view of a power cord and some components of a power supply board according to an embodiment of the disclosure.

### DETAILED DESCRIPTION

Configurations illustrated in the embodiments and the drawings described in the present disclosure are example embodiments of the disclosure, and it is to be understood that various modified examples, which may replace the embodiments and the drawings described in the present disclosure, are possible when filing the present application.

Also, like reference numerals or symbols denoted in the drawings of the present disclosure represent members or components that perform the substantially same functions.

The singular form of a noun corresponding to an item may include one or a plurality of the items unless clearly indicated otherwise in a related context.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

As used herein, the terms “portion”, “part,” module, “member” or “block” may be implemented as software or hardware. According to embodiments, a plurality of “portions”, “parts,” modules, “members” or “blocks” may be implemented as a single component, or a single “portion”, “part,” module, “member” or “block” may include a plurality of components.

Also, the terms used in the present disclosure are merely used to describe embodiments, and are not intended to limit and/or restrict the disclosure. An expression used in the singular encompasses the expression of the plural, unless it has a clearly different meaning in the context. In the present disclosure, it is to be understood that the terms such as “including” or “having,” etc., are intended to indicate the existence of the features, numbers, operations, components, parts, or combinations thereof disclosed in the disclosure, and are not intended to preclude the possibility that one or more other features, numbers, operations, components, parts, or combinations thereof may exist or may be added.

Also, it will be understood that, although the terms including ordinal numbers, such as “first”, “second”, etc., may be used herein to describe various components, these components should not be limited by these terms. These terms are only used to distinguish one component from another. For example, a first component could be termed a second component, and, similarly, a second component could be termed a first component, without departing from the scope of the disclosure. As used herein, the term “and/or” includes any and all combinations of one or more of associated listed items.

A certain (e.g., a first) component is referred to as “coupled” or “connected” with or without the terms “functionally” or “communicatively” to another (e.g., second) component. When mentioned, it means that any of the certain components can be connected to the other component directly (e.g., by wire), wirelessly, or via a third component.

It will be understood that when a certain component is referred to as being “connected to”, “coupled to”, “supported by” or “in contact with” another component, it can be directly or indirectly connected to, coupled to, supported by, or in contact with the other component. When a component is indirectly connected to, coupled to, supported by, or in contact with another component, it may be connected to, coupled to, supported by, or in contact with the other component through a third component.

It will also be understood that when a component is referred to as being “on” or “over” another component, it can be directly on the other component or intervening components may also be present.

In the following description, the terms “upper and lower directions”, “front-rear direction”, etc. are defined based on the drawings, and the shapes and positions of the components are not limited by the terms. For example, in the following description, an X direction may include a front-rear direction, a Y direction may include a left-right direction, and a Z direction may include upper and lower directions.

In the following description about various embodiments of the disclosure, for convenience of description, a display device which is a kind of electronic device will be described as an example. However, a concept of the disclosure is not limited thereto. The concept of the disclosure may be applied to various electronic devices including power supply boards.

In addition, although the disclosure describes a flat panel display device as an example, a configuration of the disclosure may also be applied to a curved display device or a bendable or flexible display device capable of changing between a flat state and a curved state. The configuration of the disclosure may be applied to all display devices regardless of the screen sizes.

Hereinafter, an embodiment of the disclosure will be described in detail with reference to the accompanying drawings.

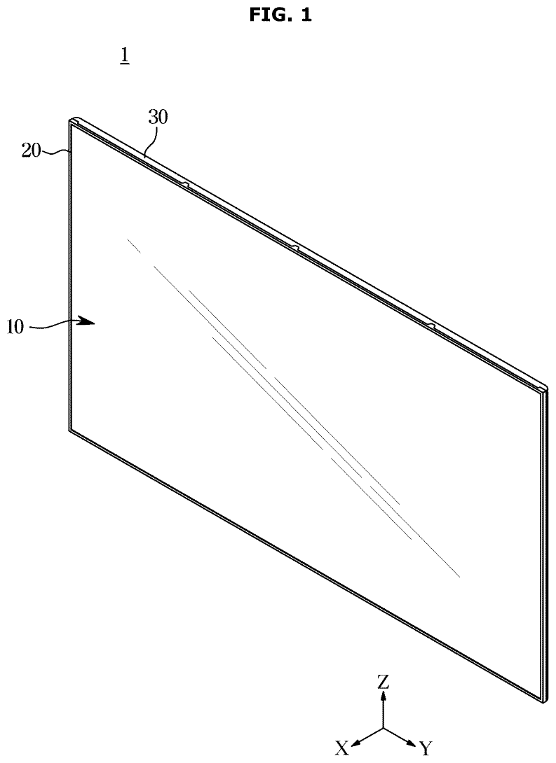

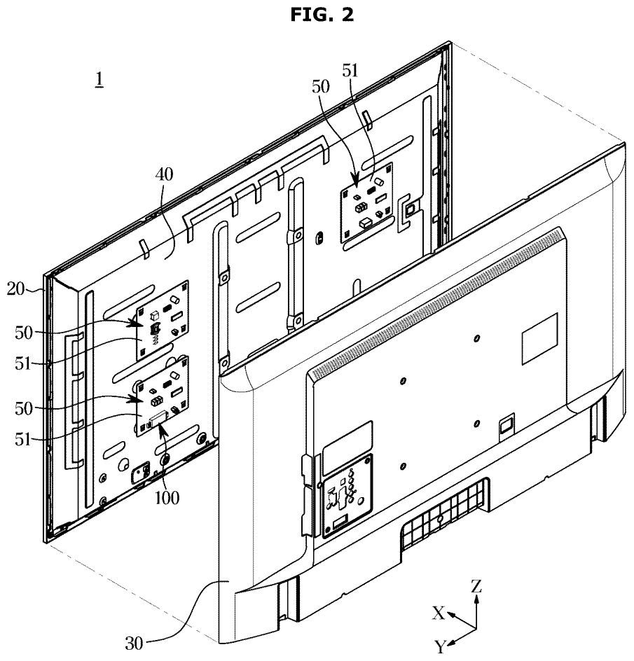

FIG. 1 shows an electronic device according to an embodiment of the disclosure. FIG. 2 shows a state in which a rear cover has been detached from an electronic device according to an embodiment of the disclosure.

Referring to FIGS. 1 and 2, an electronic device 1 according to an embodiment of the disclosure may include a display device 1.

The display device 1 may process an image signal received from outside and visually display a processed image. In FIGS. 1 and 2, the display device 1 is assumed to be a television (TV) although not limited thereto. However, the display device 1 may be implemented as one of various devices, such as a monitor, a portable multimedia device, a portable communication device, etc. That is, the display device 1 may be any kind of device that visually displays images.

Also, the display device 1 may be a large format display (LFD) that is installed in an outdoor space, such as the top of building or a bus stop. The outdoor space is not limited to an open-air space, and the display device according to an embodiment of the disclosure may be installed in any place where many peoples enter, such as a subway station, a shopping mall, a theater, an office, a store, etc., although the place is an indoor space.

Also, the display device 1 may receive content including a video signal and an audio signal from various content sources, and output video and audio corresponding to the video signal and the audio signal. For example, the display device 1 may receive content data through a broadcasting reception antenna or a wired cable, receive content data from a content reproducing device, or receive content data from a content providing server of a content provider.

The display device 1 may be configured to display a screen. The display device 1 may include a display panel 10 for displaying images in a front side.

In the display panel 10, a plurality of pixels may be formed and a screen displayed on the display panel 10 may be formed by a combination of light emitted from the plurality of pixels. For example, light emitted from the plurality of pixels may be combined like mosaic to thereby form a screen.

Each of the plurality of pixels may emit light of various brightness and various colors. Each of the plurality of pixels may include sub pixels, and the sub pixels may include a red sub pixel capable of emitting red light, a green sub pixel capable of emitting green light, and a blue sub pixel capable of emitting blue light. Each of the plurality of pixels may emit light having various brightness and various colors by a combination of light emitted from the red sub pixel, the green sub pixel, and the blue sub pixel.

The display panel 10 may be a self-emissive display panel such as Organic Light Emitting Diodes (OLEDs) or a non-emissive display panel such as a Liquid Crystal Display (LCD). A kind of the display panel 10 is not limited, and the display device 1 may include various types of display panels 10.

In the case in which the display panel 10 is a LCD panel, the display panel 10 may include a Thin Film Transistor (TFT) substrate on which TFTs are arranged in a matrix form, a color filter substrate coupled to the TFT substrate in parallel to the TFT substrate, and liquid crystals injected between the TFT substrate and the color filter substrate, wherein optical properties of the liquid crystals change depending on changes of a voltage or temperature. Also, a backlight unit (BLU) may be provided behind the display panel 10.

The backlight unit may emit light toward the display panel 10 from behind the display panel 10. In this case, the display panel 10 may block or transmit light emitted from the backlight unit.

However, the disclosure is not limited thereto, and the display panel 10 may be a self-emissive display panel such as an OLED panel as described above.

In one edge of the display panel 10, a cable for transmitting image data to the display panel 10, and a display driver integrated circuit (DDI) for processing digital image data and outputting an analog image signal may be positioned.

The display device 1 may include cases 20, 30, and 40 supporting the display panel 10. The cases 20, 30, and 40 may support a front surface, side surfaces, and a rear surface of the display panel 10.

The cases 20, 30, and 40 may form an outer appearance of the display device 1, and the cases 20, 30, and 40 may be provided with various components for enabling the display device 1 to display images or perform various functions. In FIGS. 1 and 2, the cases 20, 30, and 40 are shown as having flat plate shapes. However, the shapes of the cases 20, 30, and 40 are not limited thereto. For example, the cases 20, 30, and 40 may have curved plate shapes to correspond to a shape of the display panel 10. Also, the cases 20, 30, and 40 may be applied to a bendable or flexible display device 1 capable of changing between a flat state and a curved state.

The cases 20, 30, and 40 may include a top chassis 20 supporting the front surface and side surfaces of the display panel 10. The top chassis 20 may support the front surface of the display device 1 by forming a bezel positioned toward a front side of the display device 1. However, in the case in which the display device 1 has a very narrow bezel or is a bezel-less type, the top chassis 20 may support only the side surfaces of the display panel 10. In the case in which a bottom chassis 40 supports the side surfaces of the display panel 10, the display device 1 may not include the top chassis 20.

The display device 1 may include the bottom chassis 40 supporting a rear side of the display panel 10. The bottom chassis 40 may cover the rear side of the display panel 10 and support various components, such as a backlight unit, a printed circuit board assembly (PCBA) 50, etc. The printed circuit board assembly 50 may include a printed circuit board (PCB) 51 and various electronic components mounted on the printed circuit board 51.

In the case in which the display device 1 includes the top chassis 20, the bottom chassis 40 may be coupled to a rear side of the top chassis 20.

The display device 1 may include a rear cover 30 forming the rear surface of the display device 1. The rear cover 30 may be positioned behind the bottom chassis 40 and cover the bottom chassis 40 and the various components (for example, the printed circuit board assembly 50, etc.) mounted on a rear side of the bottom chassis 40.

As shown in FIG. 2, the printed circuit board 51 may be mounted on the cases 20, 30, and 40. The printed circuit board assembly 50 may be mounted on the bottom chassis 40. For example, the printed circuit board 51 may be mounted on the bottom chassis 40. The printed circuit board 51 may be mounted on the rear side of the bottom chassis 40. The printed circuit board assembly 50 including the printed circuit board 51 may be positioned between the bottom chassis 40 and the rear cover 30, although not limited thereto.

However, the printed circuit board 51 may be provided at various positions on the cases 20, 30, and 40.

As described above, the configuration according to a concept of the disclosure is not limited to being applied to the display device 1 and may be applied to various kinds of electronic devices 1.

The display device 1 according to an embodiment of the disclosure is also referred to as an electronic device, and the cases 20, 30, and 40 of the display device 1 are also referred to as a body of the electronic device. The body of the electronic device may be a configuration that forms an appearance of the electronic device or accommodates components required to drive the electronic device. At least one printed circuit board assembly, such as the printed circuit board assembly 50 of the display device 1, may also be mounted on the body of the electronic device.

Descriptions about the configuration of the printed circuit board of the electronic device according to a concept of the disclosure may be identical or similar to the descriptions about the configuration of the printed circuit board assembly 50 of the display device 1.

Therefore, for convenience of description, the following descriptions about an example according to a concept of the disclosure may be based on the display device 1, which is a kind of electronic device, and descriptions about other kinds of electronic devices or general descriptions about electronic devices may be omitted.

The printed circuit board assembly 50 may include the printed circuit board 51 mounted on the bottom chassis 40 of the cases 20, 30, and 40, and the electronic components mounted on the printed circuit board 51.

The printed circuit board 51 may be formed by printing a circuit line pattern with a conductive material such as copper on an electrically insulating substrate.

The circuit line pattern on the printed circuit board 51 and the electronic components mounted on the printed circuit board 51 may vary depending on functions, etc. that are provided by the printed circuit board assembly 50.

The printed circuit board assembly 50 may be provided as various kinds of printed circuit board assemblies 50 depending on functions and configurations that are provided to drive the display device 1.

For example, the printed circuit board assembly 50 may include a main board, a power supply board, a source board, etc.

The main board may include a processor and a power management device for driving the display device 1. The power supply board may supply power for driving the display device 1. The source board may control the display panel 10 of the display device 1.

A plurality of printed circuit board assemblies 50, such as the main board, the power supply board, and the source board, may be arranged independently or in combination. The printed circuit board assemblies 50 arranged independently may be electrically connected to each other to transmit/receive data, signals, or power to/from each other.

As shown in FIG. 2, the printed circuit board assembly 50 may be provided as a plurality of printed circuit board assemblies 50, and each of the plurality of printed circuit board assemblies 50 may be configured with the main board, the power supply board, the source board, etc., which have been described above. The plurality of printed circuit board assemblies 50 may be electrically connected to each other to perform a function for driving the display device 1. However, unlike this, the printed circuit board assemblies 50 may be integrated into one body to perform the function.

Hereinafter, a case in which the printed circuit board assembly 50 is a power supply board will be described as an example.

However, a concept of the disclosure is not limited to the case in which the printed circuit board assembly 50 is a power supply board 50, and the concept of the disclosure may also be applied to another kind of printed circuit board assembly 50 than a power supply board.

The power supply board 50 may receive power from an external power source and supply the power to the display device 1. The power supply board 50 may include the printed circuit board 51 and various components mounted on the printed circuit board 51 to supply power for driving the display device 1.

The power supply board 50 may include a switch mode power supply board including a switch that performs on/off switching operations, that is, a switched mode power supply (SMPS) board.

The SMPS board may be a module type power supply board that converts electricity supplied from outside into power that is usable in various electronic devices, such as a computer, a television (TV), a wireless communication device, etc., and the SMPS board may convert commercial power into high-efficiency/high-quality power required by various electronic devices by utilizing a switching function of semiconductor elements and a power conversion function of transformers and supply the high-efficiency/high-quality power. For example, the power supply board 50 may include a power converter.

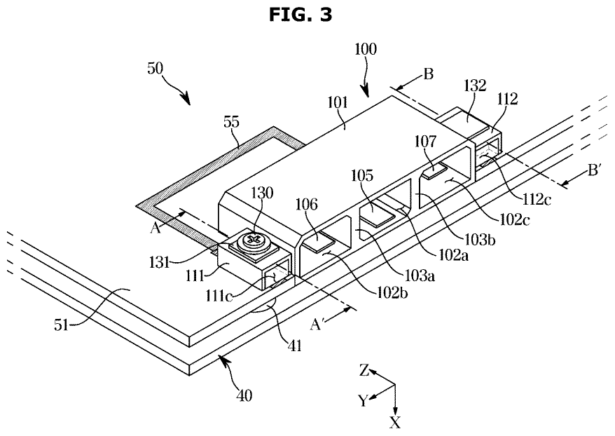

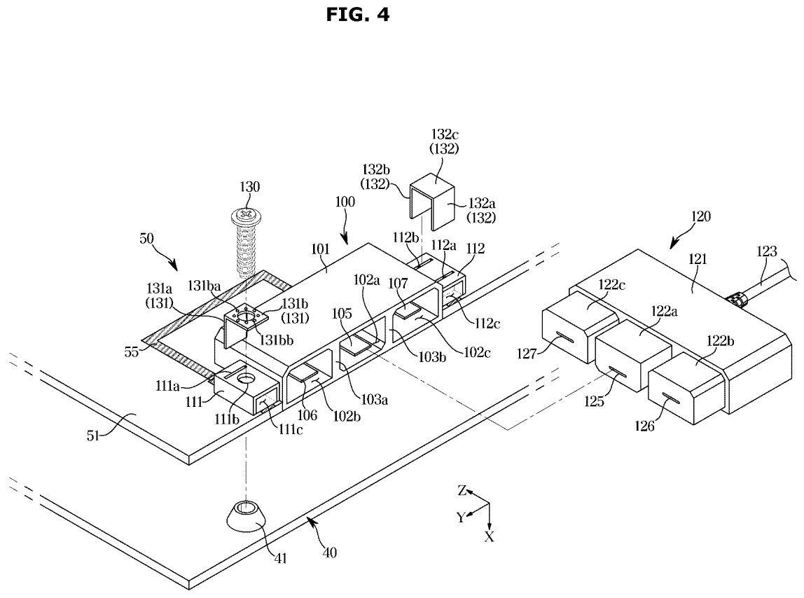

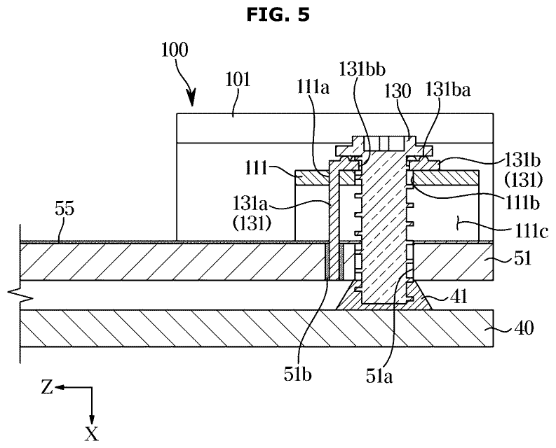

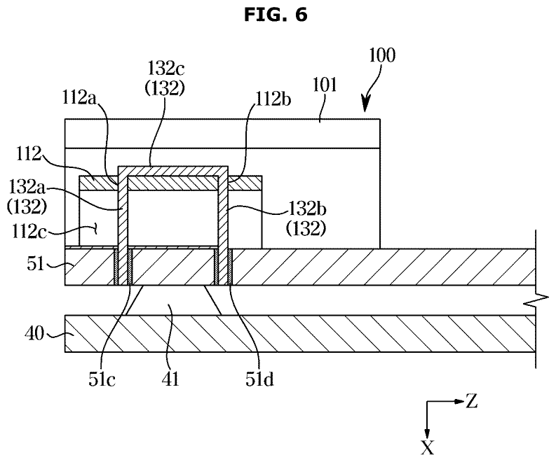

FIG. 3 shows a portion of a power supply board according to an embodiment of the disclosure. FIG. 4 is an exploded view of a power cord and some components of a power supply board according to an embodiment of the disclosure. FIG. 5 shows a cross section taken along line A-A′ denoted in FIG. 3. FIG. 6 shows a cross section taken along line B-B′ denoted in FIG. 3.

Referring to FIGS. 3 and 4, the power supply board 50 according to an embodiment of the disclosure may include a power inlet 100 that is connectable to a power cord 120. According to the power cord 120 being connected to the power inlet 100, the power supply board 50 may receive power from the power cord 120. An external power source may be an alternating current power source. The power inlet 100 may be mounted on the printed circuit board 51 of the power supply board 50.

The power inlet 100 according to an embodiment of the disclosure may include an inlet body 101. The inlet body 101 may be mounted on the printed circuit board 51 of the power supply board 50.

The inlet body 101 may include cord coupling portions 102a, 102b, and 102c to which the power cord 120 is coupled. For example, the cord coupling portions 102a, 102b, and 102c may include a first cord coupling portion 102a, a second cord coupling portion 102b, and a third cord coupling portion 102c. For example, each of the cord coupling portions 102a, 102b, and 102c may include a space capable of accommodating at least a portion of the power cord 120.

For example, the first cord coupling portion 102a, the second cord coupling portion 102b, and the third cord coupling portion 102c may be arranged in a line. Referring to FIGS. 3 and 4, the second cord coupling portion 102b may be positioned to one side of the first cord coupling portion 102a, and the third cord coupling portion 102c may be positioned to another side of the first cord coupling portion 102a, which is opposite to the one side of the first cord coupling portion 102a. The arrangement of the first cord coupling portion 102a, the second cord coupling portion 102b, and the third cord coupling portion 102c is not limited thereto. The first cord coupling portion 102a, the second cord coupling portion 102b, and the third cord coupling portion 102c may be arranged in a direction in which the printed circuit board 51 of the power supply board 50 extends. According to this configuration, the electronic device 1 according to an embodiment of the disclosure may reduce a thickness of the power supply board 50 and according to the reduction in thickness of the power supply board 50, a thickness of the electronic device 1 may also be reduced.

The power inlet 100 according to an embodiment of the disclosure may include a first terminal 105, a second terminal 106, and a third terminal 107. For example, the first terminal 105 may include a ground terminal, the second terminal 106 may include a live terminal, and the third terminal 107 may include a neutral terminal. However, the first terminal 105, the second terminal 106, and the third terminal 107 are not limited thereto. For example, the second terminal 106 may include a neutral terminal and the third terminal 107 may include a live terminal.

Hereinafter, for example, the first terminal 105 may be accommodated in the first cord coupling portion 102a, the second terminal 106 may be accommodated in the second cord coupling portion 102b, and the third terminal 107 may be accommodated in the third cord coupling portion 102c.

The inlet body 101 may include partition walls 103a and 103b that partition the first cord coupling portion 102a, the second cord coupling portion 102b, and the third cord coupling portion 102c from each other. For example, the inlet body 101 may include a first partition wall 102a that partitions the first cord coupling portion 102a and the second cord coupling portion 102b from each other, and a second partition wall 103b that partitions the first cord coupling portion 102a and the third cord coupling portion 102c from each other.

The partition walls 103a and 103b may extend from one end of the inlet body 101 to another end in a direction (for example, a Z direction) in which the power cord 120 is coupled to the power inlet 100. According to this configuration, the electronic device 1 according to an embodiment of the disclosure may improve safety by satisfying an insulation specification between the terminals 105, 106, and 107 by the partition walls 103a and 103b. In addition, the electronic device 1 according to an embodiment of the disclosure may reduce interference between the first terminal 105, the second terminal 106, and the third terminal 107.

Referring to FIGS. 3 and 4, the second terminal 106 may be positioned to the left of the first terminal 105, and the third terminal 107 may be positioned to the right of the first terminal 105. However, the positions of the second terminal 106 and the third terminal 107 are not limited thereto. The second terminal 106 may be positioned to the right of the first terminal 105, and the third terminal 107 may be positioned to the left of the first terminal 105.

The electronic device 1 according to an embodiment of the disclosure may further include the power cord 120. The power cord 120 may supply external power to the electronic device 1. The power cord 120 may be detachably coupled to the power inlet 100 of the power supply board 50. The power cord 120 may be electrically connected to the power inlet 100.

The power cord 120 according to an embodiment of the disclosure may include a cord body 121, and connector portions 122a, 122b, and 122c protruding from the cord body 121. The connector portions 122a, 122b, and 122c may be detachably coupled to the cord coupling portions 102a, 102b, and 102c of the power inlet 100. The cord body 121 of the power cord 120 may be provided with a wire 123 for receiving power from outside.

For example, the connector portions 122a, 122b, and 122c may include a first connector portion 122a, a second connector portion 122b, and a third connector portion 122c. The first connector portion 122a may be detachably coupled to the first cord coupling portion 102a, the second connector portion 122b may be detachably coupled to the second cord coupling portion 102b, and the third connector portion 122c may be detachably coupled to the third cord coupling portion 102c.

The first connector portion 122a, the second connector portion 122b, and the third connector portion 122c may be separated from each other and spaced from each other. For example, according to the power cord 120 being coupled to the power inlet 100, the first partition wall 103a may be positioned between the first connector portion 122a and the second connector portion 122b, and the second partition wall 103b may be positioned between the first connector portion 122a and the third connector portion 122c.

In the power inlet 100 according to an embodiment of the disclosure, at least one of the first cord coupling portion 102a, the second cord coupling portion 102b, or the third cord coupling portion 102c may have a shape and/or size that is different from that of another one.

For example, the first cord coupling portion 102a may have a shape that is different from those of the second cord coupling portion 102b and the third cord coupling portion 102c. A cross section of the first cord coupling portion 102a, which is perpendicular to a direction in which the power cord 120 is inserted, may have a shape that is different from a cross section of the second cord coupling portion 102b, which is perpendicular to the direction in which the power cord 120 is inserted and a cross section of the third cord coupling portion 102c, which is perpendicular to the direction in which the power cord 120 is inserted. For example, the first cord coupling portion 102a may be inclined at lower corners, and the second cord coupling portion 102b and the third cord coupling portion 102c may be inclined at upper corners. The cross section of the second cord coupling portion 102b, which is perpendicular to the direction in which the power cord 120 is inserted, may be identical to the cross section of the third cord coupling portion 102c, which is perpendicular to the direction in which the power cord 120 is inserted.

A cross section of the first connector portion 122a, which is perpendicular to the direction in which the power cord 120 is coupled to the power inlet 100, may correspond to the cross section of the first cord coupling portion 102a, which is perpendicular to the direction in which the power cord 120 is coupled to the power inlet 100. A cross section of the second connector portion 122b, which is perpendicular to the direction in which the power cord 120 is coupled to the power inlet 100, may correspond to the cross section of the second cord coupling portion 102b, which is perpendicular to the direction in which the power cord 120 is coupled to the power inlet 100. A cross section of the third connector portion 122c, which is perpendicular to the direction in which the power cord 120 is coupled to the power inlet 100, may correspond to the cross section of the third cord coupling portion 102c, which is perpendicular to the direction in which the power cord 120 is coupled to the power inlet 100.

For example, in correspondence to the first cord coupling portion 102a having a shape that is different from those of the second cord coupling portion 102b and the third cord coupling portion 102c, the first connector portion 122a may have a shape that is different from those of the second connector portion 122b and the third connector portion 122c. For example, in correspondence to the first cord coupling portion 102a being inclined at the lower corners and the second cord coupling portion 102b and the third cord coupling portion 102c being inclined at the upper corners, the first connector portion 122a may be inclined at the lower corners and the second connector portion 122b and the third connector portion 122c may be inclined at the upper corners.

In the power inlet 100 according to an embodiment of the disclosure, the first terminal 105, the second terminal 106, and the third terminal 107 may have different sizes, positions, and/or shapes. For example, a size of the second terminal 106 may be different from that of the third terminal 107. For example, a spacing distance of the first terminal 105 from the printed circuit board 51 may be different from a spacing distance of the second terminal 106 from the printed circuit board 51 and/or a spacing distance of the third terminal 107 from the printed circuit board 51. For example, an extension length of the second terminal 106 may be different from that of the third terminal 107.

The first connector portion 122a may include a first insertion portion 125 into which the first terminal 105 is insertable. The first insertion portion 125 may correspond to a size, position, and shape of the first terminal 105. According to the first connector portion 122a being coupled to the first cord coupling portion 102a, the first terminal 105 may be inserted into the first insertion portion 125.

The second connector portion 122b may include a second insertion portion 126 into which the second terminal 106 is insertable. The second insertion portion 126 may correspond to a size, position, and shape of the second terminal 106. According to the second connector portion 122b being coupled to the second cord coupling portion 102b, the second terminal 105 may be inserted into the second insertion portion 126.

The third connector portion 122c may include a third insertion portion 127 into which the third terminal 107 is insertable. The third insertion portion 127 may correspond to a size, position, and shape of the third terminal 107. According to the third connector portion 122c being coupled to the third cord coupling portion 102c, the third terminal 107 may be inserted into the third insertion portion 127.

For example, in correspondence to the size of the second terminal 106 being different from that of the third terminal 107, the size of the second insertion portion 126 may be different from that of the third insertion portion 127. For example, in correspondence to the spacing distance of the first terminal 105 from the printed circuit board 51 being different from the spacing distance of the second terminal 106 from the printed circuit board 51 and/or the spacing distance of the third terminal 107 from the printed circuit board 51, a spacing distance of the first insertion portion 125 from a lower end of the first connector portion 122a may be different from a spacing distance of the second insertion portion 126 from a lower end of the second connector portion 122b and/or a spacing distance of the third insertion portion 127 from a lower end of the third connector portion 122c.

According to this configuration, when the power cord 120 attempts to be coupled to the power inlet 100 in a wrong direction, the power cord 120 may interfere with the power inlet 100 and be prevented from being coupled with the power inlet 100. For example, when the power cord 120 rotated 180 degrees from a correct position attempts to be coupled to the power inlet 100, the power cord 120 may interfere with the power inlet 100 and be prevented from being inserted into the power inlet 100.

Referring to FIGS. 3 to 5, the power inlet 100 according to an embodiment of the disclosure may include a first fixing portion 111 for fixing the power inlet 100 on the printed circuit board 51. The first fixing portion 111 may be positioned to one side of the inlet body 101. The first fixing portion 111 may be fixed on the printed circuit board 51 by a fastening member 130 and a first fastening support 121.

The electronic device 1 according to an embodiment of the disclosure may include the fastening member 130 for fixing the first fixing portion 111 of the power inlet 100 on the printed circuit board 51. For example, the fastening member 130 may include a screw. The fastening member 130 may be screwed to the first fixing portion 111 and the printed circuit board 51.

The fastening member 130 may be installed in the bottom chassis 40 after the power inlet 100 is fixed on the printed circuit board 51. The bottom chassis 40 may include a bottom fastening portion 41 to which the fastening member 130 is fastened. For example, the fastening member 130 may be fastened to a substrate hole 51a formed in the printed circuit board 51 and the bottom fastening portion 41 of the bottom chassis 40. According to the fastening member 130 being fastened to the bottom fastening portion 41 of the bottom chassis 40, the printed circuit board 51 may be mounted on the bottom chassis 40.

The electronic device 1 according to an embodiment of the disclosure may include a first fastening support 131 fixed to the first fixing portion 111 by the fastening member 130. The first fastening support 131 may fix the first fixing portion 111 on the printed circuit board 51.

The first fastening support 131 may include a first lead portion 131a coupled to the first fixing portion 111 and the printed circuit board 51, and a washer portion 131b for improving a fastening effect of the fastening member 130. A direction in which the first lead portion 131a extends may be substantially perpendicular to a direction in which the washer portion 131b extends.

The first lead portion 131a of the first fastening support 131 may be coupled to a first lead coupling part 111a formed in the first fixing portion 111. For example, the first lead portion 131a may be inserted in the first lead coupling part 111a. For example, the first lead coupling part 111a may have a slot shape.

Referring to FIG. 5, one end of the first lead portion 131a may penetrate the first lead coupling part 111a and extend up to the printed circuit board 51. The first lead portion 131a may be positioned at a first fixing hole 51b of the printed circuit board 51. By soldering the one end of the first lead portion 131a positioned at the first fixing hole 51b of the printed circuit board 51, the first fastening support 131 may be fixed on the printed circuit board 51.

The first lead portion 131a of the first fastening support 131 positioned at the first fixing hole 51b may not protrude from the printed circuit board 51. For example, the one end of the first lead portion 131a may be positioned to correspond to one surface of the printed circuit board 51. The first lead portion 131a may be inserted into the first fixing hole 51b through a first surface of the printed circuit board 51 and may not protrude from a second surface of the printed circuit board 51.

Because the first lead portion 131a of the first fastening support 131 for fixing the power inlet 100 on the printed circuit board 51 does not protrude from the printed circuit board 51, the power supply board 50 according to an embodiment of the disclosure may be reduced in thickness.

The first fixing portion 111 may include a first supply hole 111c for stably supplying heat to a part where the first lead portion 131a is positioned while the first lead portion 131a of the first fastening support 131 is soldered on the printed circuit board 51. The first supply hole 111c may allow a part of the first lead portion 131a soldered on the printed circuit board 51 to communicate with outside of the power supply board 50. For example, the first supply hole 111c may open in a direction in which the cord coupling portions 102a, 102b, and 102c open. Because heat is stably supplied through the first supply hole 111c while the first lead portion 131a is soldered on the printed circuit board 51, the first lead portion 131a may be firmly fixed to the printed circuit board 51.

The washer portion 131b of the first fastening support 131 may be positioned between one surface of the first fixing portion 111 and the fastening member 130. The washer portion 131b may include a washer fastening hole 131bb through which the fastening member 130 passes. According to the first lead portion 131a of the first fastening support 131 being inserted into the first lead coupling portion 111a, the washer fastening hole 131bb of the washer portion 131b may be aligned with a first fastening hole 111b formed in the first fixing portion 111. While the washer fastening hole 131bb of the washer portion 131b is aligned with the first fastening hole 111b of the first fixing portion 111, the fastening member 130 may be fastened to the washer fastening hole 131bb of the washer portion 131b and the first coupling hole 111b of the first fixing portion 111, thereby fixing the power inlet 100 to the printed circuit board 51.

The washer portion 131b may include a washer protrusion 131ba for improving a fastening force with the fastening member 130. According to the fastening member 130 being fastened to the first fastening support 131, the washer protrusion 131ba may come in contact with the fastening member 130. For example, at least one washer protrusion 131ba may be provided around a circumference of the washer fastening hole 131bb. While the fastening member 130 is fastened to the first fastening support 131 and the first fixing portion 111 to fix the power inlet 100, the fastening member 130 may come in contact with the washer protrusion 131ba of the washer portion 131b, thereby improving a fastening force.

In the electronic device 1 according to an embodiment of the disclosure, because the power inlet 100 is fixed on the printed circuit board 51 by the fastening member 130, the power inlet 100 may be prevented from being damaged or departing from the printed circuit board 51 when a greater force than a preset magnitude is applied to the power cord 120 connected to the power inlet 100. In addition, in the electronic device 1 according to an embodiment of the disclosure, because the fastening member 130 requires a relatively small space to fix the power inlet 100 to the printed circuit board 51, utilization of space of the power supply board 50 may be improved.

In the case in which the first terminal 105 includes a ground terminal, the power supply board 50 according to an embodiment of the disclosure may include a ground pattern 55 for connecting the fastening member 130 to the first terminal 105 according to the fastening member 130 being fastened to the first fixing portion 111 to fix the power inlet 100 on the printed circuit board 51. The ground pattern 55 may be provided on the printed circuit board 51 to connect the first terminal 105 to the fastening member 130. By the ground pattern 55, current flowing into the first terminal 105 may pass to a shield part, although not limited thereto. However, in the case in which the second terminal 106 includes a ground terminal, the ground pattern 55 may be connected to the second terminal 106, and, in the case in which the third terminal 107 includes a ground terminal, the ground pattern 55 may be connected to the third terminal 107.

For example, the ground pattern 55 may be soldered with the first fastening support 131. According to the ground pattern 55 being connected to the first fastening support 131 by soldering, the fastening member 130 fastened to the first fastening support 131 may be grounded with the ground pattern 55.

Referring to FIGS. 3, 4, and 6, the power inlet 100 according to an embodiment of the disclosure may include a second fixing portion 112 for fixing the power inlet 100 on the printed circuit board 51. The second fixing portion 112 may be positioned to another side of the inlet body 101, which is opposite to the one side of the inlet body 101 to which the first fixing portion 111 is positioned. The second fixing portion 112 may be fixed on the printed circuit board 51 by a second fastening support 132.

The electronic device 1 according to an embodiment of the disclosure may include a second fastening support 132 for fixing the second fixing portion 112 of the power inlet 100 on the printed circuit board 51. The second fastening support 132 may include a second lead portion 132a and a third lead portion 132b coupled to the second fixing portion 112 and the printed circuit board 51, and a connecting portion 132c connecting the second lead portion 132a and the third lead portion 132b. For example, the second lead portion 132a and the third lead portion 132b may extend in parallel to each other, and the connecting portion 132c may extend substantially perpendicular to the second lead portion 132a and the third lead portion 132b.

The second lead portion 132a of the second fastening support 132 may be coupled to a second lead coupling part 112a formed in the second fixing portion 112. For example, the second lead portion 132a may be inserted into the second lead coupling part 112a. For example, the second lead coupling part 112a may have a slot shape. The third lead portion 132b of the second fastening support 132 may be coupled to a third lead coupling part 112b formed in the second fixing portion 112. For example, the third lead portion 132b may be inserted into the third lead coupling part 112b. For example, the third lead coupling part 112b may have a slot shape.

Referring to FIG. 6, one end of the second lead portion 132a may penetrate the second lead coupling part 112a and extend up to the printed circuit board 51. The second lead portion 132a may be positioned at a second fixing hole 51c of the printed circuit board 51. One end of the third lead portion 132b may penetrate the third lead coupling part 112b and extend up to the printed circuit board 51. The third lead portion 132b may be positioned at a third fixing hole 51d of the printed circuit board 51.

By soldering the second fastening support 132 while one end of the second lead portion 132 is positioned at the second fixing hole 51c of the printed circuit board 51 and one end of the third lead portion 132b is positioned at the third fixing hole 51d of the printed circuit board 51, the second fastening support 132 may be fixed on the printed circuit board 51.

The second lead portion 132a of the second fastening support 132 positioned at the second fixing hole 51c may not protrude from the printed circuit board 51. For example, the one end of the second lead portion 132a may be positioned to correspond to one surface of the printed circuit board 51. The second lead portion 132a may be inserted into the second fixing hole 51c through the first surface of the printed circuit board 51 and may not protrude from the second surface of the printed circuit board 51.

The third lead portion 132b of the second fastening support 132 positioned at the third fixing hole 51d may not protrude from the printed circuit board 51. For example, the one end of the third lead portion 132b may be positioned to correspond to one surface of the printed circuit board 51. The third lead portion 132b may be inserted into the third fixing hole 51d through the first surface of the printed circuit board 51 and may not protrude from the second surface of the printed circuit board 51.

Because the second lead portion 132a and the third lead portion 132b of the second fastening support 132 for fixing the power inlet 100 on the printed circuit board 51 do not protrude from the printed circuit board 51, the power supply board 50 according to an embodiment of the disclosure may be reduced in thickness.

The second fixing portion 112 may include a second supply hole 112c for stably supplying heat to parts where the second lead portion 132a and the third lead portion 132b are positioned while the second lead portion 132a and the third lead portion 132b of the second fastening support 132 are soldered on the printed circuit board 51. The second supply hole 112c may allow parts of the second lead portion 132a and the third lead portion 132b soldered on the printed circuit board 51 to communicate with the outside of the power supply board 50. For example, the second supply hole 112c may open in the direction in which the cord coupling portions 102a, 102b, and 102c open. Because heat is stably supplied through the second supply hole 112c while the second lead portion 132a and the third lead portion 132c are soldered on the printed circuit board 51, the second lead portion 132a and the third lead portion 132b may be firmly fixed on the printed circuit board 51.

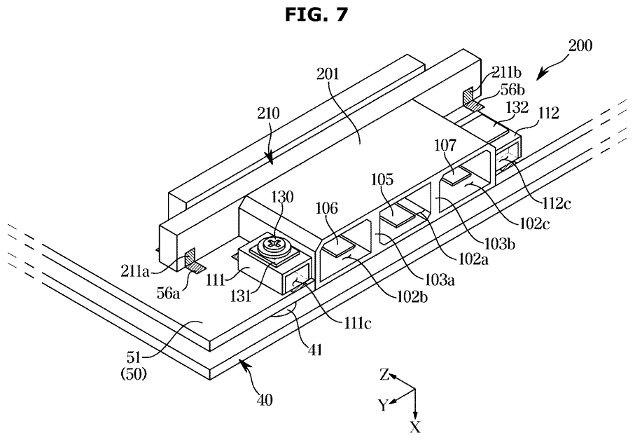

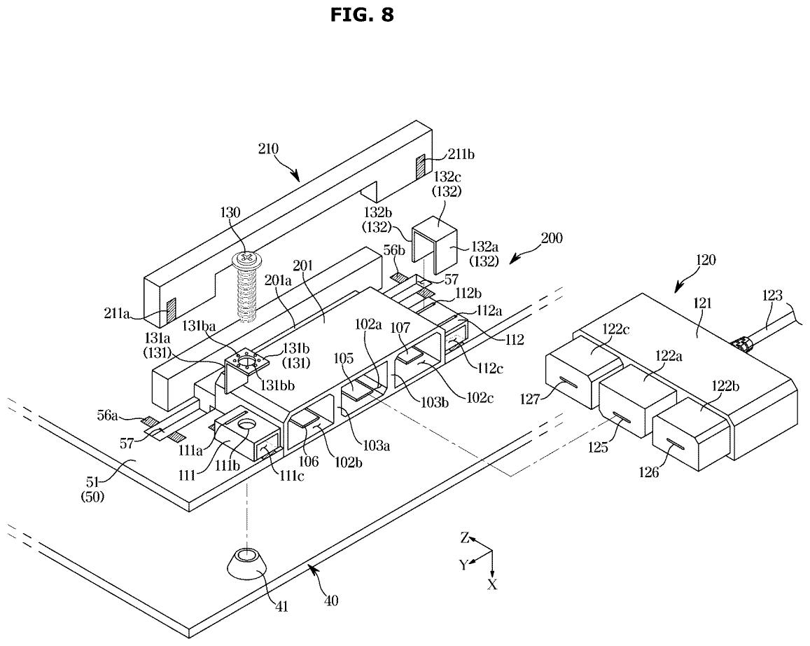

FIG. 7 shows a portion of a power supply board according to an embodiment of the disclosure. FIG. 8 is an exploded view of a power cord and some components of a power supply board according to an embodiment of the disclosure.

A power inlet 200 of the power supply board 50 according to an embodiment of the disclosure will be described with reference to FIGS. 7 and 8. In the following descriptions about the power inlet 200 of the power supply board 50 shown in FIGS. 7 and 8, the same components as those of the power supply board 50 shown in FIGS. 1 to 6 will be assigned like reference numerals, and detailed descriptions thereof will be omitted.

Referring to FIGS. 7 and 8, the power supply board 50 according to an embodiment of the disclosure may include the power inlet 200, and a fixing substrate 210 for fixing the power inlet 200 on the printed circuit board 51.

The power inlet 200 according to an embodiment of the disclosure may include the first terminal 105, the second terminal 106, and the third terminal 107. The power inlet 200 may include the first cord coupling portion 102a in which the first terminal 105 is accommodated, the second cord coupling portion 102b in which the second terminal 106 is accommodated, and the third cord coupling portion 102c in which the third terminal 107 is accommodated. The power inlet 200 may include the first fixing portion 111 and the second fixing portion 112 for fixing the power inlet 200 on the printed circuit board 51. The first fixing portion 111 may be fixed on the printed circuit board 51 by the fastening member 130 and the first fastening support 131. The second fixing portion 112 may be fixed on the printed circuit board 51 by the second fastening support 132.

By mounting the fixing substrate 210 according to an embodiment of the disclosure on the printed circuit board 51, the fixing substrate 210 may fix the power inlet 200 on the printed circuit board 51. The fixing substrate 210 mounted on the printed circuit board 51 may press at least a portion of the power inlet 200 toward the printed circuit board 51.

The power inlet 200 may include a substrate mounting portion 201a on which the fixing substrate 210 is mounted. The substrate mounting portion 201a may be formed in a portion of the inlet body 201. The substrate mounting portion 201a may have a shape and/or size corresponding to a shape and/or size of the fixing substrate 210. For example, the substrate mounting portion 201a may be formed by denting a portion of the inlet body 201. At least a portion of the fixing substrate 210 may be inserted into the substrate mounting portion 201a of the power inlet 200.

The printed circuit board 51 of the power supply board 50 may include a substrate accommodating portion 57 for accommodating at least a portion of the fixing substrate 210. For example, at least a portion of both end portions of the fixing substrate 210 may be inserted into the substrate accommodating portion 57.

For example, the fixing substrate 210 may connect patterns formed on the printed circuit board 51. The fixing substrate 210 may include a first substrate connecting portion 211a connected to one part 56a of the patterns formed on the printed circuit board 51, and a second substrate connecting portion 211b connected to another part 56b of the patterns formed on the printed circuit board 51. For example, the one part 56a of the patterns of the printed circuit board 51 may be soldered with the first substrate connecting portion 211a of the fixing substrate 210, and the other part 56b of the patterns of the printed circuit board 51 may be soldered with the second substrate connecting portion 211b of the fixing substrate 210. According to both end portions of the fixing substrate 210 being inserted into the substrate accommodating portion 57 and the substrate connecting portions 211a and 211b being soldered with the one part 56a and the other part 56b of the patterns of the printed circuit board 51, the fixing substrate 210 may be fixed on the printed circuit board 51. The one part 56a and the other part 56b of the patterns formed on the printed circuit board 51 may be connected to each other by the fixing substrate 210.

According to this configuration, the power inlet 200 according to an embodiment of the disclosure may be prevented from being damaged or departing from the printed circuit board 51 even when a greater force than a preset magnitude is applied thereto.

Referring to FIGS. 2 and 7, for example, the fixing substrate 210 may protrude from the printed circuit board 51 toward the rear cover 30, and accordingly, the fixing substrate 210 may cushion an impact transferred from the rear cover 30 to the power supply board 50.

An electronic device according to an embodiment of the disclosure may include a printed circuit board; and a power inlet provided on the printed circuit board. The power inlet may include a first terminal, a second terminal at a first side of the first terminal, a third terminal at a second side of the first terminal, the second side being opposite to the first side, a first fixing portion fixed on the printed circuit board by a fastening member, and a first fastening support soldered on the printed circuit board and configured to fix the first fixing portion on the printed circuit board.

The power inlet may comprise a first cord coupling portion accommodating the first terminal, a second cord coupling portion accommodating the second terminal and partitioned from the first cord coupling portion, and a third cord coupling portion accommodating the third terminal and partitioned from the first cord coupling portion.

The power inlet may comprise a first partition wall partitioning the first cord coupling portion from the second cord coupling portion, and a second partition wall partitioning the first cord coupling portion from the third cord coupling portion.

The electronic device may further include a power cord configured to be detachably coupled to the power inlet. A cross section of the first cord coupling portion, which is perpendicular to a direction in which the power cord is coupled, may have a shape that is different from a cross section of the second cord coupling portion, which is perpendicular to the direction in which the power cord is coupled or a cross section of the third cord coupling portion, which is perpendicular to the direction in which the power cord is coupled.

The power cord may comprise a first connector portion configured to be inserted into the first cord coupling portion, a second connector portion configured to be inserted into the second cord coupling portion, and spaced from a first side of the first connector portion, and a third connector portion configured to be inserted into the third cord coupling portion, and spaced from a second side of the first connector portion, the second side being opposite to the first side of the first connector portion.

The fastening member may be configured to be coupled to the first fastening support.

The first fastening support may comprise a first lead portion soldered on the printed circuit board. The printed circuit board may comprise a first fixing hole accommodating the first lead portion. The first lead portion may be accommodated in the first fixing hole through a first surface of the printed circuit board without protruding from a second surface of the printed circuit board, the second surface being opposite to the first surface.

The first fixing portion may comprise a first supply hole configured to allow heat to be supplied to the part of the first lead portion soldered on the printed circuit board.

The first fastening support may comprise a washer portion between the fastening member and the first fixing portion. The washer portion may comprise a washer protrusion protruding toward the fastening member.

The first terminal may comprise a ground terminal. The fastening member may be grounded with the ground terminal according to the first fastening support being connected to a ground pattern provided on the printed circuit board by soldering.

The first fixing portion may be at a first end of the power inlet. The power inlet may comprise a second fixing portion at a second end of the power inlet, the second end being opposite to the first end of the power inlet, and a second fastening support configured to fix the second fixing portion on the printed circuit board by being soldered on the printed circuit board.

The second fastening support may comprise a second lead portion of which a part is soldered on the printed circuit board. The printed circuit board may comprise a second fixing hole accommodating the second lead portion. The second lead portion may be accommodated in the second fixing hole through a first surface of the printed circuit board without protruding from a second surface of the printed circuit board, the second surface being opposite to the first surface.

The second fixing portion may comprise a second supply hole formed to allow heat to be supplied to the part of the second lead portion soldered on the printed circuit board.

The electronic device may further include a display panel, and a bottom chassis covering the display panel. The fastening member may be fastened to the bottom chassis.

A display device according to an embodiment of the disclosure may include a display panel, and a power supply board configured to receive power to be supplied to the display panel, the power supply board comprising a printed circuit board and a power inlet mounted on the printed circuit board. The power inlet may include a first cord coupling portion, a second cord coupling portion at a first side of the first cord coupling portion and partitioned from the first cord coupling portion, a third cord coupling portion at a second side of the first cord coupling portion, the second side being opposite to the first side, the third cord coupling portion partitioned from the first cord coupling portion, a first fixing portion fixed on the printed circuit board according to a first fastening support being soldered on the printed circuit board, the first fixing portion comprising a first supply hole configured to allow heat to be supplied to a part of the first fastening support being soldered, and a fastening member fastened to the first fixing portion and the first fastening support and configured to fix the power inlet on the printed circuit board.

The first fastening support may include a washer protrusion protruding toward the fastening member upon fastening of the fastening member.

The power inlet may include a second fixing portion being fixed on the printed circuit board according to a second fastening support being soldered on the printed circuit board, the second fixing portion including a second supply hole formed to allow heat to be supplied to a part of the second fastening support being soldered.

The display device may further include a power cord configured to be detachably coupled to the power inlet. The power inlet may include a first partition wall partitioning the first cord coupling portion from the second cord coupling portion and extending in a direction in which the power cord is coupled to the power inlet, and a second partition wall partitioning the first cord coupling portion from the third cord coupling portion and extending in the direction in which the power cord is coupled to the power inlet.

A cross section of the first cord coupling portion, which is perpendicular to the direction in which the power cord is coupled, may be different from a cross section of the second cord coupling portion, which is perpendicular to the direction in which the power cord is coupled or a cross section of the third cord coupling portion, which is perpendicular to the direction in which the power cord is coupled.

The power inlet may include a ground terminal. The fastening member may be grounded with the ground terminal according to the first fastening support being connected to a ground pattern provided on the printed circuit board by soldering.

According to a concept of the disclosure, the electronic device and the display device may be reduced in thickness because the fastening support soldered on the printed circuit board to fix the power inlet on the printed circuit board does not protrude from the printed circuit board.

According to a concept of the disclosure, the electronic device and the display device may improve safety because the power inlet is mounted on the printed circuit board by screwing of the fastening member and soldering of the fastening member.

Effects that may be achieved according to the disclosure are not limited to the above-mentioned effects, and other effects not mentioned will be clearly understood by one of ordinary skill in the technical field to which the disclosure belongs from the following descriptions.

Embodiments have been shown and described. However, the disclosure is not limited to the above-described embodiments, and various modifications can be made by one of ordinary skill in the technical art to which the disclosure belongs without departing from the gist of the technical idea of the disclosure defined by the claims below.

What is claimed is:

1. An electronic device comprising:
a printed circuit board; and
a power inlet provided on the printed circuit board,
wherein the power inlet comprises:
a first terminal;
a second terminal at a first side of the first terminal;
a third terminal at a second side of the first terminal, the second side being opposite to the first side;
a first fixing portion fixed on the printed circuit board by a fastening member; and
a first fastening support soldered on the printed circuit board and configured to fix the first fixing portion on the printed circuit board.

2. The electronic device of claim 1, wherein the power inlet comprises:
a first cord coupling portion accommodating the first terminal;
a second cord coupling portion accommodating the second terminal and partitioned from the first cord coupling portion; and
a third cord coupling portion accommodating the third terminal and partitioned from the first cord coupling portion.

3. The electronic device of claim 2, wherein the power inlet comprises:
a first partition wall partitioning the first cord coupling portion from the second cord coupling portion; and
a second partition wall partitioning the first cord coupling portion from the third cord coupling portion.

4. The electronic device of claim 2, further comprising a power cord configured to be detachably coupled to the power inlet,
wherein a cross section of the first cord coupling portion, which is perpendicular to a direction in which the power cord is coupled, has a shape that is different from a cross section of the second cord coupling portion, which is perpendicular to the direction in which the power cord is coupled, or a cross section of the third cord coupling portion, which is perpendicular to the direction in which the power cord is coupled.

5. The electronic device of claim 4, wherein the power cord comprises:
a first connector portion configured to be inserted into the first cord coupling portion;
a second connector portion configured to be inserted into the second cord coupling portion, and spaced from a first side of the first connector portion; and
a third connector portion configured to be inserted into the third cord coupling portion, and spaced from a second side of the first connector portion, the second side being opposite to the first side of the first connector portion.

6. The electronic device of claim 1, wherein the fastening member is configured to be coupled to the first fastening support.

7. The electronic device of claim 1, wherein the first fastening support comprises a first lead portion soldered on the printed circuit board,
wherein the printed circuit board comprises a first fixing hole accommodating the first lead portion, and
wherein the first lead portion is accommodated in the first fixing hole through a first surface of the printed circuit board without protruding from a second surface of the printed circuit board, the second surface being opposite to the first surface.

8. The electronic device of claim 7, wherein the first fixing portion comprises a first supply hole configured to allow heat to be supplied to the part of the first lead portion soldered on the printed circuit board.

9. The electronic device of claim 1, wherein the first fastening support comprises a washer portion between the fastening member and the first fixing portion, and
wherein the washer portion comprises a washer protrusion protruding toward the fastening member.

10. The electronic device of claim 1, wherein the first terminal comprises a ground terminal, and
wherein the fastening member is grounded with the ground terminal according to the first fastening support being connected to a ground pattern provided on the printed circuit board by soldering.

11. The electronic device of claim 1, wherein the first fixing portion is at a first end of the power inlet, and
wherein the power inlet comprises:
a second fixing portion at a second end of the power inlet, the second end being opposite to the first end of the power inlet; and
a second fastening support configured to fix the second fixing portion on the printed circuit board by being soldered on the printed circuit board.

12. The electronic device of claim 11, wherein the second fastening support comprises a second lead portion of which a part is soldered on the printed circuit board,
wherein the printed circuit board comprises a second fixing hole accommodating the second lead portion, and
wherein the second lead portion is accommodated in the second fixing hole through a first surface of the printed circuit board without protruding from a second surface of the printed circuit board, the second surface being opposite to the first surface.

13. The electronic device of claim 12, wherein the second fixing portion comprises a second supply hole formed to allow heat to be supplied to the part of the second lead portion soldered on the printed circuit board.

14. The electronic device of claim 1, further comprising:
a display panel; and
a bottom chassis covering the display panel,
wherein the fastening member is fastened to the bottom chassis.

15. A display device comprising:
a display panel; and
a power supply board configured to receive power to be supplied to the display panel, the power supply board comprising a printed circuit board and a power inlet mounted on the printed circuit board, wherein the power inlet comprises:
a first cord coupling portion;
a second cord coupling portion at a first side of the first cord coupling portion and partitioned from the first cord coupling portion;
a third cord coupling portion at a second side of the first cord coupling portion, the second side being opposite to the first side, the third cord coupling portion partitioned from the first cord coupling portion;
a first fixing portion fixed on the printed circuit board according to a first fastening support being soldered on the printed circuit board, the first fixing portion comprising a first supply hole configured to allow heat to be supplied to a part of the first fastening support being soldered; and
a fastening member fastened to the first fixing portion and the first fastening support and configured to fix the power inlet on the printed circuit board.
